(19) United States
(12) Patent Application Publication
(10) Pub. No.: US 2024/0258978 A1
(43) Pub. Date: Aug. 1, 2024

(54) EFFICIENT FRONT-END MODULE STRUCTURE AND MOBILE DEVICE INCLUDING THE SAME

(71) Applicant: SKYWORKS SOLUTIONS, INC., Irvine, CA (US)

(72) Inventors: Roman Zbigniew Arkiszewski, Oak Ridge, NC (US); Jeffrey Gordon Strahler, Greensboro, NC (US)

(21) Appl. No.: 18/426,485

(22) Filed: Jan. 30, 2024

Related U.S. Application Data
(60) Provisional application No. 63/442,539, filed on Feb. 1, 2023.

(51) Int. Cl. H03F 3/24; H03F 3/195; H04B 1/10

(52) U.S. Cl. CPC H03F 3/245; H03F 3/195; H04B 1/1027; H03F 2200/451; H04B 2001/1054

(57) ABSTRACT

A radio frequency (RF) module comprising a plurality of input terminals configured to receive a plurality of RF signals from a transceiver, the RF signals being delivered through a plurality of narrowband carriers, a combiner, a power amplifier, a filter, and an output terminal. The combiner is configured to combine the plurality of RF signals into a combined RF signal in a broadband carrier. The power amplifier is configured to amplify the combined RF signal and to generate an amplified RF signal. The filter is configured to filter the amplified RF signal and to generate a filtered RF signal, and the output terminal is configured to output the filtered RF signal to an antenna.

### CROSS-REFERENCE TO RELATED APPLICATIONS

This application claims priority under 35 U.S.C. § 119(e) to U.S. Provisional Patent Application Ser. No. 63/442,539, titled “EFFICIENT FRONT-END MODULE STRUCTURE AND MOBILE DEVICE INCLUDING THE SAME,” filed Feb. 1, 2023, the entire contents of which is incorporated herein by reference for all purposes.

### BACKGROUND

### Field

Aspects and embodiments of the present disclosure relate to electronic systems, and in particular, to front-end modules in radio frequency (RF) electronics.

### Description of Related Technology

In current mobile devices, there is sophisticated circuitry inside an RF front-end module that is responsible for converting information from the near-zero frequency baseband signals used to convey information and data to radio-signals that can be received or transmitted over the air. The RF front-end module needs to process the right data at the right time with the right information and send it with the right band at the right power level. Generally, the RF front-end is implemented in a module which is disposed between a transceiver and an antenna.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### SUMMARY

According to an aspect of the present disclosure, a radio frequency (RF) module is provided. The RF module comprises a plurality of input terminals configured to receive a plurality of RF signals from a transceiver, the RF signals being delivered through a plurality of narrowband carriers, a combiner configured to combine the plurality of RF signals into a combined RF signal in a broadband carrier, a power amplifier configured to amplify the combined RF signal and to generate an amplified RF signal, a filter configured to filter the amplified RF signal and to generate a filtered RF signal, and an output terminal configured to output the filtered RF signal to an antenna.

According to one example, the RF module is a front-end module.

According to another example, each of the plurality of narrowband carriers has a first bandwidth. In one embodiment, the first bandwidth is about 100 MHz. In another embodiment, the broadband carrier has a second bandwidth broader than the first bandwidth.

According to another example, the combined RF signal is a sum of the respective RF signals in different narrowband carriers that are not overlapping with each other.

In another example, the RF module further includes a power management integrated chip (PMIC) configured to control power management of the RF module. In one embodiment, the PMIC is a buck/boost converter or an envelope tracker.

In another example, the RF module is capable of multi-input and multi-output operation for signal transmission. In one embodiment, an order of the combiner is equal to a number of inputs and the outputs of the MIMO operation.

According to another aspect of the present disclosure, a mobile device is provided. The mobile device comprises an antenna configured to receive a radio frequency (RF) signal, and a front end system configured to communicate with the antenna. The front end system includes a plurality of input terminals configured to receive a plurality of RF signals from a transceiver, the RF signals being delivered through a plurality of narrowband carriers, a combiner configured to combine the plurality of RF signals into a combined RF signal in a broadband carrier, a power amplifier configured to amplify the combined RF signal and to generate an amplified RF signal, a filter configured to filter the amplified RF signal and to generate a filtered RF signal, and an output terminal configured to output the filtered RF signal to the antenna.

According to one example, each of the plurality of narrowband carriers has a first bandwidth. In one embodiment, the first bandwidth is about 100 MHz. In another embodiment, the broadband carrier has a second bandwidth broader than the first bandwidth.

In another example, the combined RF signal is a sum of the respective RF signals in different narrowband carriers that are not overlapping with each other.

In a further example, the RF module further includes a power management integrated chip (PMIC) configured to control power management of the RF module. In one embodiment, the PMIC is a buck/boost converter or an envelope tracker.

In another example, the RF module is capable of multi-input and multi-output operation for signal transmission. In one embodiment, an order of the combiner is equal to a number of inputs and the outputs of the MIMO operation.

### BRIEF DESCRIPTION OF THE DRAWINGS

FIG. 1 is a schematic diagram of one example of a communication network.

FIG. 2A is a schematic diagram of one example of a downlink channel using multi-input and multi-output (MIMO) communications.

FIG. 2B is schematic diagram of one example of an uplink channel using MIMO communications.

FIG. 3 is a schematic diagram of one embodiment of a mobile device.

FIG. 4 depicts an example wireless device having one or more advantageous features described herein.

FIG. 5 is a schematic diagram illustrating an example of process taking place in the transceiver in a wireless device.

FIG. 6 is a schematic diagram of an example of wireless device structure.

FIG. 7 is a schematic diagram of example of wireless device structure according to an embodiment of the present disclosure.

FIG. 8 is a schematic diagram of an example of conventional wireless device structure for MIMO.

FIG. 9 is a schematic diagram of an example of wireless device structure for MIMO according to an embodiment.

FIG. 10 is an example of simulated result of wireless device structure.

FIG. 11 is an example of simulated result of wireless device structure.

FIG. 12 is an example of simulated result of wireless device structure.

FIG. 13A is a schematic diagram of one embodiment of a packaged module.

FIG. 13B is a schematic diagram of a cross-section of the packaged module of FIG. 13A taken along the lines 13A-13B.

FIG. 14 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

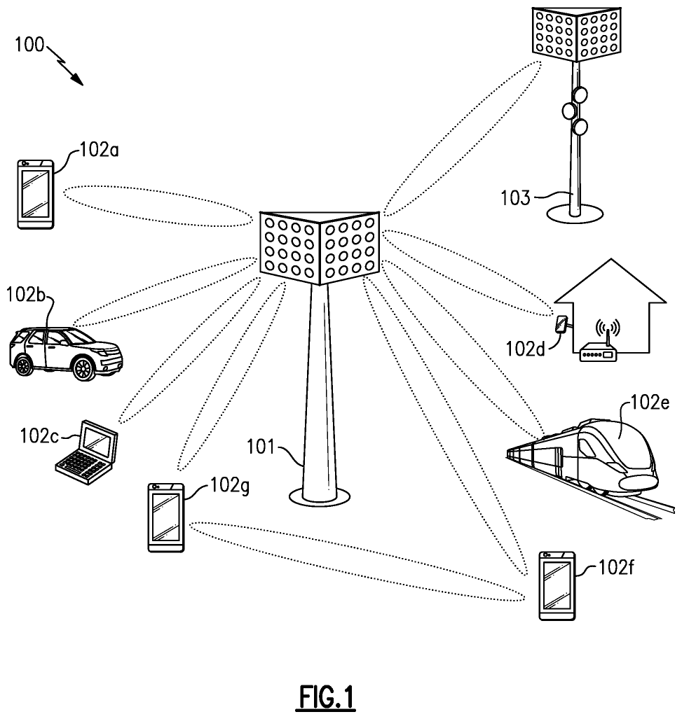

FIG. 1 is a schematic diagram of one example of a communication network 100. The communication network 100 includes a macro cell base station 101, a small cell base station 103, and various examples of user equipment (UE), including a first mobile device 102a, a wireless-connected car 102b, a laptop 102c, a stationary wireless device 102d, a wireless-connected train 102e, a second mobile device 102f, and a third mobile device 102g.

Although specific examples of base stations and user equipment are illustrated in FIG. 1, a communication network can include base stations and user equipment of a wide variety of types and/or numbers.

For instance, in the example shown, the communication network 100 includes the macro cell base station 101 and the small cell base station 103. The small cell base station 103 can operate with relatively lower power, shorter range, and/or with fewer concurrent users relative to the macro cell base station 101. The small cell base station 103 can also be referred to as a femtocell, a picocell, or a microcell. Although the communication network 100 is illustrated as including two base stations, the communication network 100 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 100 of FIG. 1 supports communications using a variety of cellular technologies, including, for example, 4G LTE and 5G NR. In certain implementations, the communication network 100 is further adapted to provide a wireless local area network (WLAN), such as WiFi. Although various examples of communication technologies have been provided, the communication network 100 can be adapted to support a wide variety of communication technologies.

Various communication links of the communication network 100 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 100 can be implemented to support self-fronthaul and/or self-backhaul (for instance, as between mobile device 102g and mobile device 102f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE (High Power User Equipment) power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 100 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 100 of FIG. 1 can be used to support a wide variety of advanced communication features, including, but not limited to, eMBB, uRLLC, and/or mMTC.

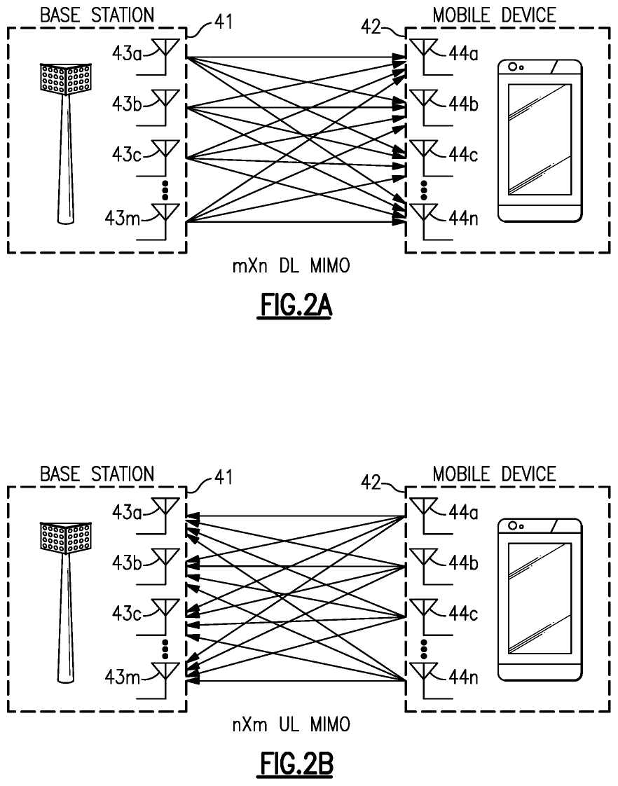

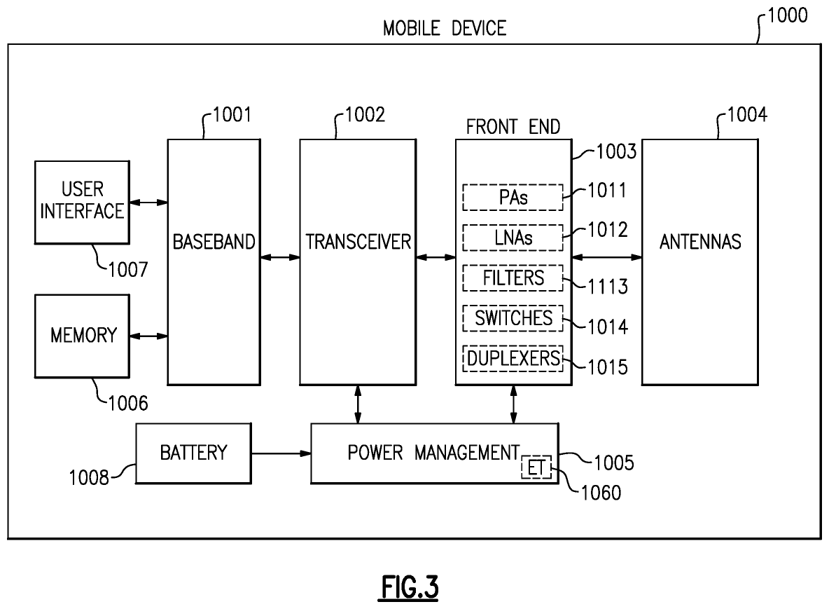

FIG. 2A is a schematic diagram of one example of a downlink channel using multi-input and multi-output (MIMO) communications. FIG. 2B is a schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas. In the example shown in FIG. 2A, downlink MIMO communications are provided by transmitting using M antennas 43a, 43b, 43c, . . . 43m of the base station 41 and receiving using N antennas 44a, 44b, 44c, . . . 44 n of the mobile device 42. Accordingly, FIG. 2A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 2B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 2B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

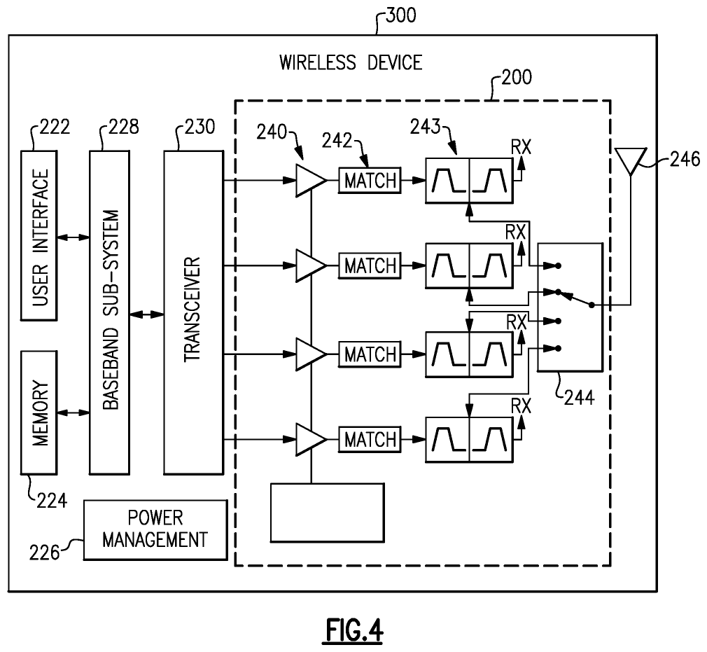

FIG. 3 is a schematic diagram of one example of a mobile device 1000. The mobile device 1000 includes a baseband system 1001, a transceiver 1002, a front end system 1003, antennas 1004, a power management system 1005, a memory 1006, a user interface 1007, and a battery 1008.

The mobile device 1000 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 1002 generates RF signals for transmission and processes incoming RF signals received from the antennas 1004. It will be understood that various functionalities associated with the transmission and receiving of RF signals can be achieved by one or more components that are collectively represented in FIG. 3 as the transceiver 1002. In one example, separate components (for instance, separate circuits or dies) can be provided for handling certain types of RF signals.

The front end system 1003 aids in conditioning signals transmitted to and/or received from the antennas 1004. In the illustrated embodiment, the front end system 1003 includes power amplifiers (PAs) 1011, low noise amplifiers (LNAs) 1012, filters 1013, switches 1014, and duplexers 1015. However, other implementations are possible.

For example, the front end system 1003 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 1000 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 1004 can include antennas used for a wide variety of types of communications. For example, the antennas 1004 can include antennas associated transmitting and/or receiving signals associated with a wide variety of frequencies and communications standards.

In certain implementations, the antennas 1004 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 1000 can operate with beamforming in certain implementations. For example, the front end system 1003 can include phase shifters having variable phase controlled by the transceiver 1002. Additionally, the phase shifters are controlled to provide beam formation and directivity for transmission and/or reception of signals using the antennas 1004. For example, in the context of signal transmission, the phases of the transmit signals provided to the antennas 1004 are controlled such that radiated signals from the antennas 1004 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 1004 from a particular direction. In certain implementations, the antennas 1004 include one or more arrays of antenna elements to enhance beamforming.

The baseband system 1001 is coupled to the user interface 1007 to facilitate processing of various user input and output (I/O), such as voice and data. The baseband system 1001 provides the transceiver 1002 with digital representations of transmit signals, which the transceiver 1002 processes to generate RF signals for transmission. The baseband system 1001 also processes digital representations of received signals provided by the transceiver 1002. As shown in FIG. 3, the baseband system 1001 is coupled to the memory 1006 to facilitate operation of the mobile device 1000.

The memory 1006 can be used for a wide variety of purposes, such as storing data and/or instructions to facilitate the operation of the mobile device 1000 and/or to provide storage of user information.

The power management system 1005 provides a number of power management functions of the mobile device 1000. The power management system 1005 of FIG. 3 includes an envelope tracker 1060. As shown in FIG. 3, the power management system 1005 receives a battery voltage form the battery 1008. The battery 1008 can be any suitable battery for use in the mobile device 1000, including, for example, a lithium-ion battery.

The mobile device 1000 of FIG. 3 illustrates one example of an RF communication system that can include power amplifier(s) implemented in accordance with one or more features of the present disclosure. However, the teachings herein are applicable to RF communication systems implemented in a wide variety of ways.

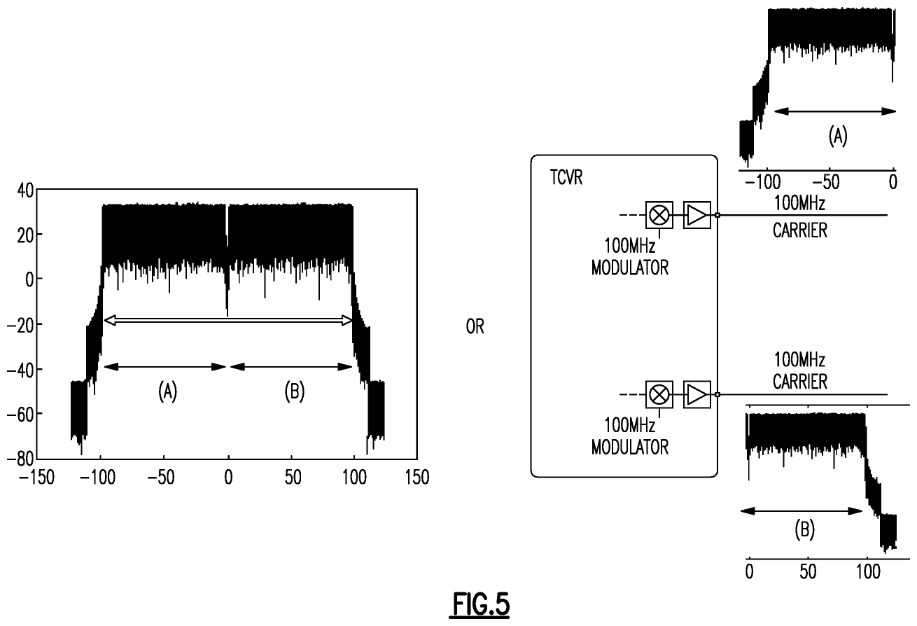

FIG. 4 depicts an example wireless device 300 having one or more advantageous features described in further detail below. In the context of a module having one or more features as described herein, such a module can be generally depicted by a dashed box 200, and can be implemented as, for example, a front-end module (FEM).

Referring to FIG. 4, power amplifiers (PAs) 240 may receive their respective RF signals from a transceiver 230 that can be configured and operated in known manners to generate RF signals to be amplified and transmitted, and to process received signals. The transceiver 230 is shown to interact with a baseband sub-system 228 that is configured to provide conversion between data and/or voice signals suitable for a user and RF signals suitable for the transceiver 230. The transceiver 230 can also be in communication with a power management component 226 that is configured to manage power for the operation of the wireless device 300. Such power management can also control operations of the baseband sub-system 228 and the module 200.

The baseband sub-system 228 is shown to be connected to a user interface 222 to facilitate various input and output of voice and/or data provided to and received from the user. The baseband sub-system 228 can also be connected to a memory 224 that is configured to store data and/or instructions to facilitate the operation of the wireless device, and/or to provide storage of information for the user.

In the example wireless device 300, outputs of the PAs 240 are shown to be matched (via respective match circuits 242) and routed to their respective duplexers 243. Such amplified and filtered signals can be routed to an antenna 246 through an antenna switch 244 for transmission. In some embodiments, the duplexers 243 can allow transmit and receive operations to be performed simultaneously using a common antenna (e.g., 246). In FIG. 4, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antennas, and additional connectivity features such as WiFi, Bluetooth, and GPS.

With the introduction of the 5G NR air interface standards 3GPP has allowed for operation of carriers with significantly wider modulation bandwidths (200 MHz+). Unfortunately, certain popular transceivers in use today have limited modulation bandwidth capability and are limited to a maximum of 100 MHz bandwidth for the carriers they can generate. This forces customers to generate two (or more) separate carriers to support the desired operating bandwidths.

FIG. 5 is a schematic diagram illustrating an example of processes taking place in the transceiver in a wireless device.

Commonly used transceivers may generate either a 200 MHz carrier or 2×100 MHz carriers. Sometimes the transceiver has limited modulation bandwidth, so the transceiver needs to modulate carriers with limited bandwidth, for example 100 MHz, to generate a wider modulation bandwidth (e.g., 200 MHZ).

According to this example, the system uses multiple outputs with a bandwidth of less than 100 MHz from the transceiver and routes them to separate power amplifiers, power management integrated chip (PMICs), filters, and antennas in the system.

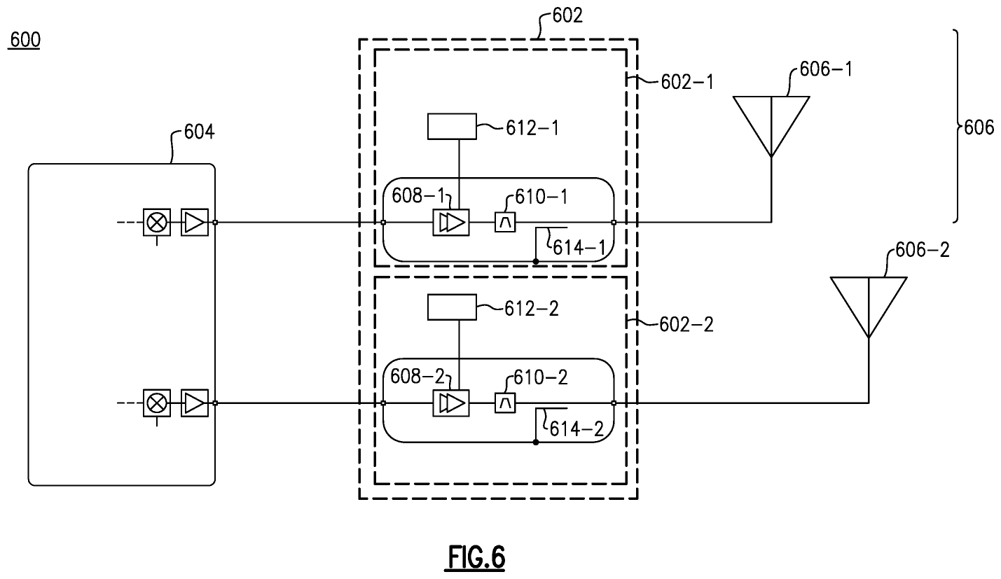

FIG. 6 is a schematic diagram of an example of wireless mobile structure.

In FIG. 6, at least a part of the wireless device structure 600 is illustrated. The wireless device structure 600 may include a front-end module 602 disposed between the transceiver 604 and antenna(s) 606 (606-1, 606-2). The transceiver 604 is configured to separate carriers (for example, bandwidth of 100 MHz for each carrier) and transmit the carriers to the front-end module 602 through separate signal paths.

In this example, the front-end module 602 has two sub front-end modules 602-1, 602-2. Each of the sub front-end module 602-1, 602-2 is configured to process the respective input signals, separately. More specifically, the sub front-end module 602-1 includes a power amplifier 608-1, a filter 610-1, a power management integrated chip (PMIC) 612-1, and a coupler 614-1. Similarly, the sub front-end module 602-2 includes a power amplifier 608-2, a filter 610-2, a PMIC 612-2, and a coupler 614-2.

In addition, the front-end module 602 transmits the separate processed signals to respective antennas 606-1, 606-2, separately.

This results in doubling the number of power amplifiers, PMICs, filters, and antennas required to support operation with the bandwidth limitations of the transceiver.

It is also noted that for HB and UHB wide bandwidth cases conventional systems may use Envelope Tracking (ET) PMICs in order to achieve efficiency targets. This further adds to the cost and complexity of the system by requiring two ET modulators to support each of the power amplifiers. It is also noted that 100 MHz can be considered to be a practical limit of an ET system, potentially contributing to a continued use of 100 MHz maximum bandwidth transceiver modulation and advocating of a solution involving multiple PAs.

In some embodiments, a power combiner (for example, a Wilkinson style combiner) is used inside the Power Amplifier (PA) module input section to combine the two signals from the transceiver. The new combined waveform is then be amplified by a single broadband PA. In this configuration, the single broadband PA only needs a single PMIC, a single filter, and a single antenna to support the entire system. This saves layout space and cost by eliminating at least one PA, at least one PMIC, at least one filter, and at least one antenna from the system. The addition of the power combiner may only add modest cost and size given that it only needs to support low power (<10 dBm) operation.

Although any broadband PA design could be used, it is noted that the broadband PA could easily be realized with known technology and that additional savings could be realized by using a simple buck/boost PMIC.

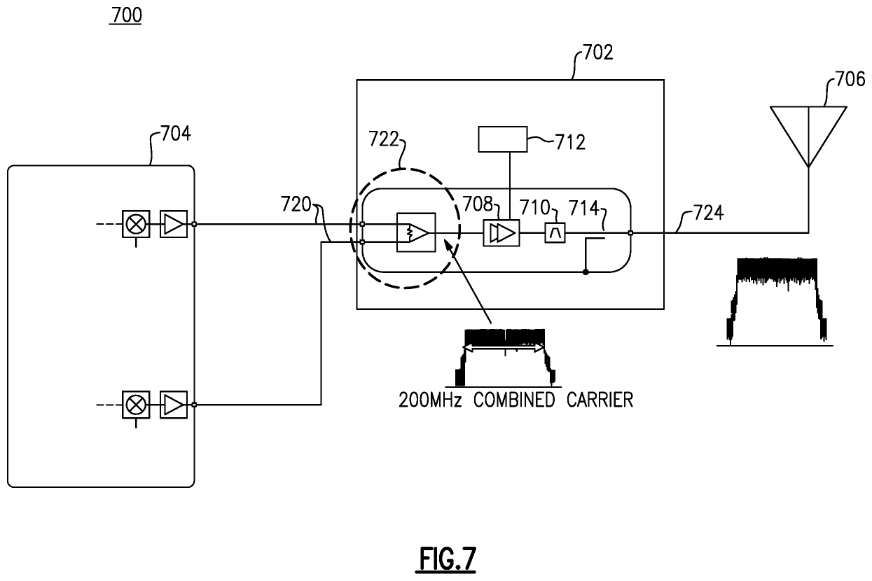

FIG. 7 is a schematic diagram of example of mobile device structure 700 according to an embodiment of the present disclosure.

As shown in FIG. 7, the mobile device structure 700 includes a front-end module 702 disposed between the transceiver 704, and antenna 706. In this example, the mobile device structure 700 does not require additional antennas.

The front-end module 702 may include a power amplifier 708, a filter 710, a PMIC 712, and a coupler 714, as similar to the structure 600 shown in FIG. 6. The power amplifier 708, as shown, may include one or more power amplifier stages. However, the mobile device structure 700 of FIG. 7 may include only one signal path because the signal passing the combiner 722 may be a combined signal.

The front-end module 702 includes a plurality of input terminals 720, a combiner 722, a power amplifier 708, a filter 710, and an output terminal 724. According to an embodiment, the front-end module 702 may further include a PMIC 712, and a coupler 714.

The plurality of input terminals 720 are configured to receive respective RF signals from a transceiver 704. Although two input terminals are illustrated in FIG. 7 as an example, the number of input terminals is not limited thereto.

The respective RF signals may be delivered through respective narrowband carriers. For example, each of the respective narrowband carriers may have a bandwidth (first bandwidth) of 100 MHz.

The combiner 722 is configured to combine the respective RF signals into a combined RF signal in a broadband carrier. For example, the broadband carrier may have a bandwidth of 200 MHz. According to an embodiment, the combined RF signal may be a sum of the respective RF signals in different narrowband carriers that are not overlapping with each other.

The power amplifier 708 is configured to amplify the combined RF signal. The filter 710 is configured to filter the amplified RF signal. The output terminal 724 is configured to output the filtered RF signal to the antenna 706. The signal output at the output terminal 724 may be a single combined signal such that only one antenna 706 is required.

The PMIC 712 may be configured to control power management of the front-end module 702. According to an embodiment, the PMIC 712 may be a buck/boost converter or an envelope tracker.

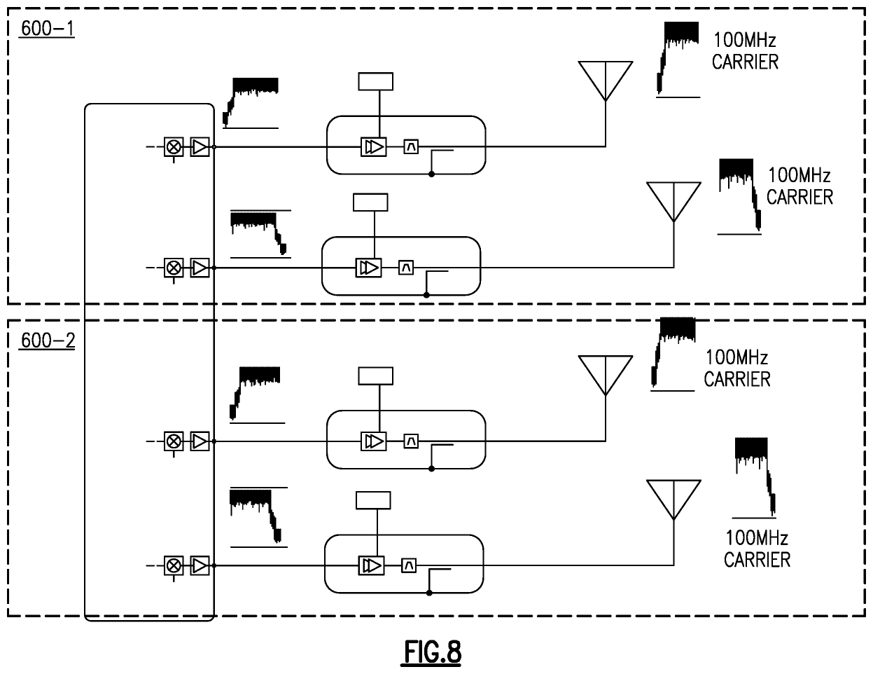

FIG. 8 is a schematic diagram of an example of conventional wireless device structure for multiple input/multiple output (MIMO) operation. In this example, the wireless device structure is capable of 2×200 MHz 2×2 UL MIMO.

As shown in FIG. 8, referring back to FIG. 6, the structure 600 of FIG. 6 is extended to two structures 600-1, 600-2 to support 2×2 MIMO. According to this example, this results in doubling the number of power amplifiers, PMICs, filters, and antennas required to support operation with the bandwidth limitations of the transceiver.

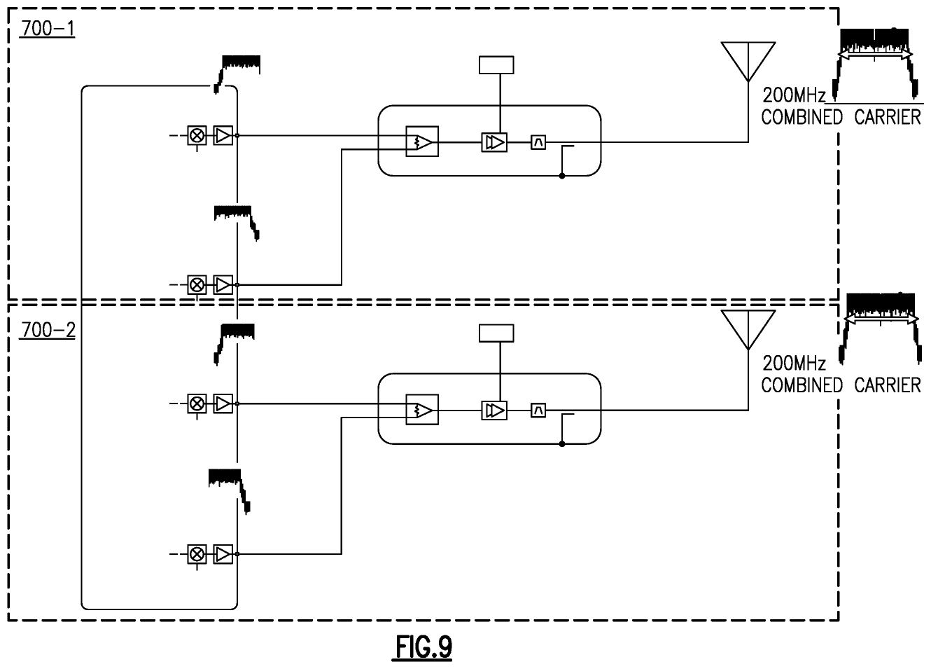

FIG. 9 is a schematic diagram of an example of wireless device structure for MIMO operation according to an embodiment of the present disclosure. In this embodiment, the wireless device structure is capable of 2×200 MHz 2×2 UL MIMO.

As shown in FIG. 9, referring back to FIG. 7, the structure of 700 of FIG. 7 is extended according to the dimension of MIMO operation. In this embodiment, the wireless device structure 700 is extended to two sub structures 700-1, 700-2.

Compared to the structure of FIG. 8, each of the sub structures 700-1, 700-2 will only need a single PMIC, a single filter, and a single antenna to support the entire subsystem. This will save layout space and cost by eliminating at least one PA, at least one PMIC, at least one filter, and at least one antenna from the subsystems.

According to embodiments of the present disclosure, the additional PAs, filters, antennas, and PMICs are not necessary. Since a fewer number of elements are required, the implementation of the front end design involves much lower costs. In addition, embodiments of the present disclosure require significantly less space to implement. Furthermore, by using only one PA, advanced broadband PA technology, and a single PMIC, embodiments of the present disclosure provide significantly higher efficiency. Additionally, the single PA may include a Wilkinson line combiner at the module input. Embodiments of the present disclosure may allow the use of a single less costly buck/boost PMIC instead of an ET modulator to achieve better overall system efficiency.

FIG. 10 is an example of simulated results of a wireless device structure. A complementary cumulative distribution function (CCDF) curve shows how much of the time the signal is at or above a given power level. As shown in FIG. 10, when same data set is used in each carrier, the combined CCDF curve has a PAPR ˜2.5 dB higher than a single carrier.

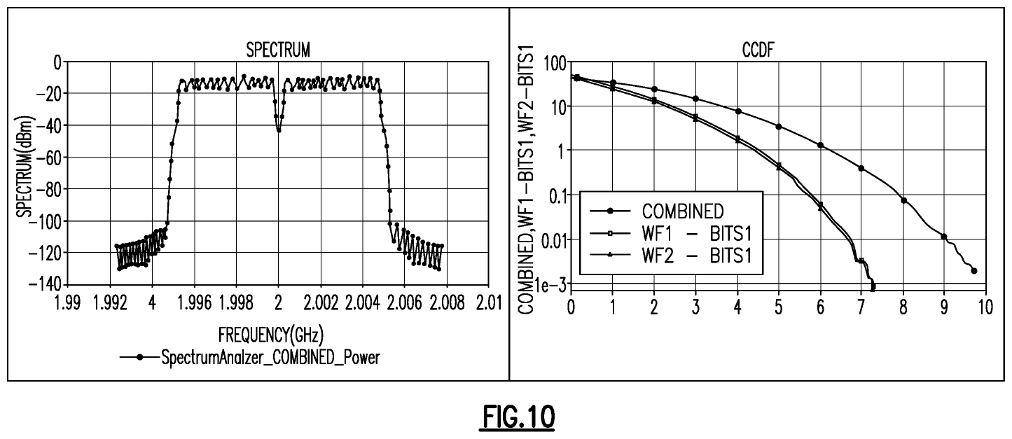

FIG. 11 is another example of simulated result of a wireless device structure. As shown in FIG. 11, when different data sets are used in each carrier, the combined CCDF curve has a PAPR ˜1 dB higher than a single carrier.

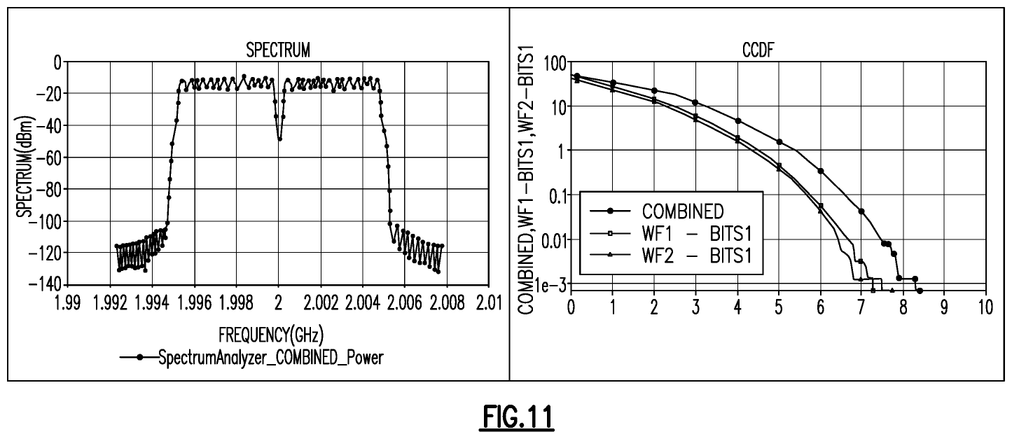

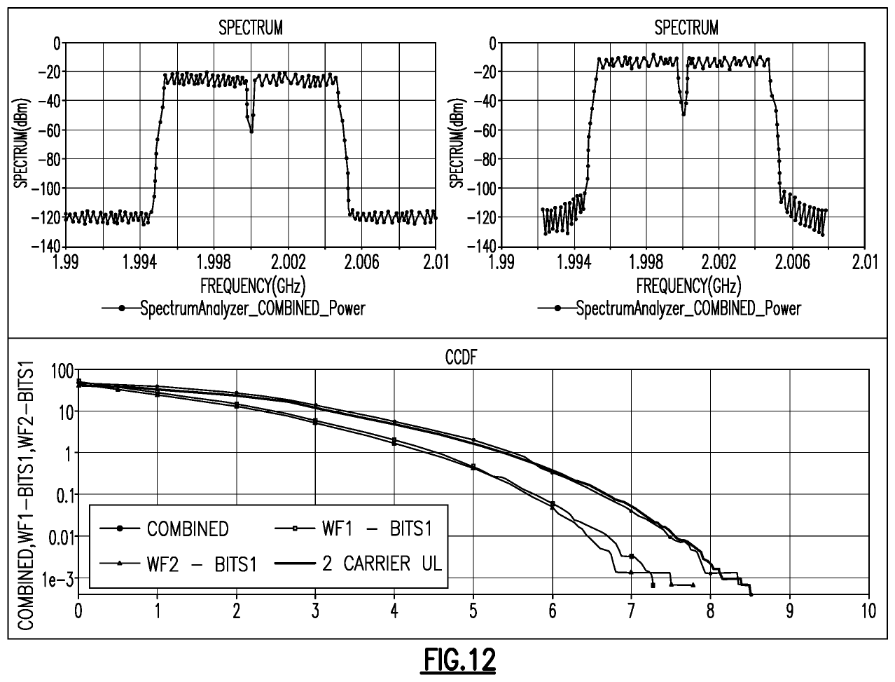

FIG. 12 is a further example of simulated result of a wireless device structure. This graph shows a comparison with a dual carrier uplink (UL) waveform (WF). It can be seen that a combined WF and a dual carrier UL WF have very similar envelope characteristics. Both require ˜1 dB more headroom than a single carrier.

From FIGS. 10, 11 and 12, it can be seen that there is no difference or no significant difference in the WF characteristics of the two combined WFs compared to the broadband reference case. Therefore, a combining method of reconstructing the broadband WF in the system does not pose any challenges related to the natural envelope characteristics of the reference WF.

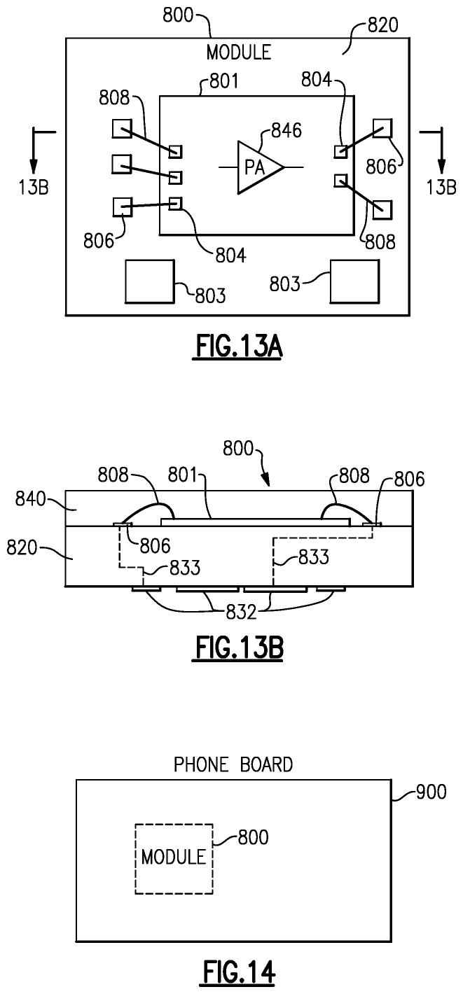

FIG. 13A is a schematic diagram of one embodiment of a packaged module 800. FIG. 13B is a schematic diagram of a cross-section of the packaged module 800 of FIG. 13A taken along the lines 13B-13B.

The packaged module 800 includes an IC or die 801, surface mount components 803, wirebonds 808, a package substrate 820, and encapsulation structure 840. The package substrate 820 includes pads 806 formed from conductors disposed therein. Additionally, the die 801 includes pads 804, and the wirebonds 808 have been used to electrically connect the pads 804 of the die 801 to the pads 806 of the package substrate 801.

The die 801 includes a power amplifier 846, which can be implemented in accordance with any of the embodiments herein.

The packaging substrate 820 can be configured to receive a plurality of components such as the die 801 and the surface mount components 803, which can include, for example, surface mount capacitors and/or inductors.

As shown in FIG. 13B, the packaged module 800 is shown to include a plurality of contact pads 832 disposed on the side of the packaged module 800 opposite the side used to mount the die 801. Configuring the packaged module 800 in this manner can aid in connecting the packaged module 800 to a circuit board such as a phone board of a wireless device. The example contact pads 832 can be configured to provide RF signals, bias signals, power low voltage(s) and/or power high voltage(s) to the die 801 and/or the surface mount components 803. As shown in FIG. 13B, the electrical connections between the contact pads 832 and the die 801 can be facilitated by connections 833 through the package substrate 820. The connections 833 can represent electrical paths formed through the package substrate 820, such as connections associated with vias and conductors of a multilayer laminated package substrate.

In some embodiments, the packaged module 800 can also include one or more packaging structures to, for example, provide protection and/or facilitate handling of the packaged module 800. Such a packaging structure can include overmold or encapsulation structure 840 formed over the packaging substrate 820 and the components and die(s) disposed thereon.

It will be understood that although the packaged module 800 is described in the context of electrical connections based on wirebonds, one or more features of the present disclosure can also be implemented in other packaging configurations, including, for example, flip-chip configurations.

FIG. 14 is a schematic diagram of one embodiment of a phone board 900. The phone board 900 includes the module 800 shown in FIGS. 13A-13B attached thereto. Although not illustrated in FIG. 14 for clarity, the phone board 900 can include additional components and structures.

### Applications

Some of the embodiments described above have provided examples in connection with wireless devices or mobile phones. However, the principles and advantages of the embodiments can be used for any other systems or apparatus that have needs for power amplifiers.

Such RF modules can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A radio frequency (RF) module comprising:
a plurality of input terminals configured to receive a plurality of RF signals from a transceiver, the RF signals being delivered through a plurality of narrowband carriers;
a combiner configured to combine the plurality of RF signals into a combined RF signal in a broadband carrier;
a power amplifier configured to amplify the combined RF signal and to generate an amplified RF signal;
a filter configured to filter the amplified RF signal and to generate a filtered RF signal; and
an output terminal configured to output the filtered RF signal to an antenna.

2. The RF module of claim 1 wherein the RF module is a front-end module.

3. The RF module of claim 1 wherein each of the plurality of narrowband carriers has a first bandwidth.

4. The RF module of claim 3 wherein the first bandwidth is about 100 MHz.

5. The RF module of claim 3 wherein the broadband carrier has a second bandwidth broader than the first bandwidth.

6. The RF module of claim 1 wherein the combined RF signal is a sum of the respective RF signals in different narrowband carriers that are not overlapping with each other.

7. The RF module of claim 1 wherein the RF module further includes a power management integrated chip (PMIC) configured to control power management of the RF module.

8. The RF module of claim 7 wherein the PMIC is a buck/boost converter or an envelope tracker.

9. The RF module of claim 1 wherein the RF module is capable of multi-input and multi-output operation for signal transmission.

10. The RF module of claim 9 wherein an order of the combiner is equal to a number of inputs and the outputs of the MIMO operation.

11. A mobile device comprising:
an antenna configured to receive a radio frequency (RF) signal; and
a front end system configured to communicate with the antenna, the front end system including a plurality of input terminals configured to receive a plurality of RF signals from a transceiver, the RF signals being delivered through a plurality of narrowband carriers, a combiner configured to combine the plurality of RF signals into a combined RF signal in a broadband carrier, a power amplifier configured to amplify the combined RF signal and to generate an amplified RF signal, a filter configured to filter the amplified RF signal and to generate a filtered RF signal, and an output terminal configured to output the filtered RF signal to the antenna.

12. The mobile device of claim 11 wherein each of the plurality of narrowband carriers has a first bandwidth.

13. The mobile device of claim 12 wherein the first bandwidth is about 100 MHz.

14. The mobile device of claim 12 wherein the broadband carrier has a second bandwidth broader than the first bandwidth.

15. The mobile device of claim 11 wherein the combined RF signal is a sum of the respective RF signals in different narrowband carriers that are not overlapping with each other.

16. The mobile device of claim 11 wherein the RF module further includes a power management integrated chip (PMIC) configured to control power management of the RF module.

17. The mobile device of claim 16 wherein the PMIC is a buck/boost converter or an envelope tracker.

18. The mobile device of claim 11 wherein the RF module is capable of multi-input and multi-output operation for signal transmission.

19. The mobile device of claim 18 wherein an order of the combiner is equal to a number of inputs and the outputs of the MIMO operation.
